(19) United States
(12) Patent Application Publication
(10) Pub. No.: US 2026/0136751 A1
(43) Pub. Date: May 14, 2026

(54) DISPLAY PANEL, METHOD FOR MANUFACTURING THE SAME, AND DISPLAY DEVICE

(71) Applicant: TCL CHINA STAR OPTOELECTRONICS TECHNOLOGY CO., LTD., Shenzhen (CN)

(72) Inventors: Haofeng ZHANG, Shenzhen (CN); Jiangbo YAO, Shenzhen (CN); Zhifu LI, Shenzhen (CN)

(73) Assignee: TCL CHINA STAR OPTOELECTRONICS TECHNOLOGY CO., LTD., Shenzhen (CN)

(21) Appl. No.: 19/022,331

(22) Filed: Jan. 15, 2025

Related U.S. Application Data
(63) Continuation of application No. PCT/CN2024/134737, filed on Nov. 27, 2024.

(30) Foreign Application Priority Data
Nov. 11, 2024 (CN) 202411600791.1

(51) Int. Cl. H10K 50/115; H10K 59/12; H10K 59/35; H10K 85/60

(52) U.S. Cl. CPC H10K 50/115; H10K 85/654; H10K 59/1201; H10K 59/35

(57) ABSTRACT

A display panel includes a plurality of first electrodes, a plurality of auxiliary portions, and a plurality of light-emitting portions. The auxiliary portions are disposed on a side of the first electrodes; the light-emitting portions are disposed on a side of the auxiliary portions away from the first electrodes; the auxiliary portions include a first material; the light-emitting portions include quantum dots and connecting structures connected between the quantum dots; and the connecting structures are formed by a second material substituted by a crosslinking structure, the second material is the same as the first material, and the quantum dots are connected by the connecting structures through the crosslinking structure.

### CROSS-REFERENCE TO RELATED APPLICATIONS

This application is a continuation application of International Application No. PCT/CN2024/134737, filed on Nov. 27, 2024, which claims the priority to and benefit of Chinese Patent Application No. 202411600791.1, filed on Nov. 11, 2024, the disclosure of which is incorporated herein by reference in its entirety.

### TECHNICAL FIELD

The disclosure relates to the field of display, and in particular, to a display panel, a method for manufacturing the same, and a display device.

### BACKGROUND

Quantum dots are extremely tiny semiconductor nanocrystals that are invisible to the naked eye, with a particle size of less than 10 nanometers. Generally, the quantum dots are composed of a zinc atom, a cadmium atom, a selenium atom, and a sulfur atom. The quantum dots have a distinctive characteristic, that is, whenever stimulated by light or electricity, they emit colored light. The color of the light is determined by the material and size of the quantum dots, which allows the quantum dots to change the color of the light emitted by a light source.

A quantum dot light-emitting diode (QLED) display panel has advantages such as wide color gamut, high purity, high brightness, low voltage, and extremely thin appearance, making it highly promising for development.

At present, a photolithography process is often used to prepare the QLED display panel. However, during the patterning process of a quantum dot light-emitting layer in a preset light-emitting area, the material of the quantum dot light-emitting layer is prone to remain in other light-emitting areas, which may affect the color gamut and the display effect of the display panel.

### SUMMARY

Some embodiments of the disclosure provide a display panel, including:
a first electrode layer including a plurality of first electrodes;
an auxiliary layer disposed on a side of the first electrode layer, in which the auxiliary layer includes a plurality of auxiliary portions disposed corresponding to the plurality of first electrodes respectively, and each of the plurality of auxiliary portions is disposed on a side of one of the plurality of first electrodes;
a light-emitting layer disposed on a side of the auxiliary layer away from the first electrode layer, in which the light-emitting layer includes a plurality of light-emitting portions disposed corresponding to the plurality of auxiliary portions respectively, and each of the light-emitting portions is disposed on a side of one of the auxiliary portions away from corresponding one of the plurality of first electrodes; and
a second electrode layer disposed on a side of the light-emitting layer away from the auxiliary layer;
in which the auxiliary portions include a first material, and the light-emitting portions include quantum dots and connecting structures connected between the quantum dots;
and the connecting structures are formed by a second material substituted by a crosslinking structure, the second material is the same as the first material, and the quantum dots are connected by the connecting structures through the crosslinking structure.

Some embodiments of the disclosure provide a method for manufacturing a display panel, including the following steps:
forming a first electrode layer including a plurality of first electrodes;
forming an auxiliary layer and a light-emitting layer on a side of the first electrode layer, in which the light-emitting layer is disposed on a side of the auxiliary layer away from the first electrode layer, the auxiliary layer includes a plurality of auxiliary portions disposed corresponding to the plurality of first electrodes respectively, and the light-emitting layer includes a plurality of light-emitting portions disposed corresponding to the plurality of auxiliary portions respectively; each of the plurality of auxiliary portions is disposed on a side of one of the plurality of first electrodes, and each of the light-emitting portions is disposed on a side of one of the auxiliary portions away from corresponding one of the plurality of first electrodes; the auxiliary portions include a first material, and the light-emitting portions include quantum dots and connecting structures connected between the quantum dots; and the connecting structures are formed by a second material substituted by a crosslinking structure, the second material is the same as the first material, and the quantum dots are connected by the connecting structures through the crosslinking structure; and
forming a second electrode layer on a side of the light-emitting layer away from the auxiliary layer.

Some embodiments of the disclosure further provide a display device including a display panel, the display panel includes:
a first electrode layer including a plurality of first electrodes;
an auxiliary layer disposed on a side of the first electrode layer, in which the auxiliary layer includes a plurality of auxiliary portions disposed corresponding to the plurality of first electrodes respectively, and each of the plurality of auxiliary portions is disposed on a side of one of the plurality of first electrodes;
a light-emitting layer disposed on a side of the auxiliary layer away from the first electrode layer, in which the light-emitting layer includes a plurality of light-emitting portions disposed corresponding to the plurality of auxiliary portions respectively, and each of the light-emitting portions is disposed on a side of one of the auxiliary portions away from corresponding one of the plurality of first electrodes; and
a second electrode layer disposed on a side of the light-emitting layer away from the auxiliary layer;
in which the auxiliary portions include a first material, and the light-emitting portions include quantum dots and connecting structures connected between the quantum dots; and the connecting structures are formed by a second material substituted by a crosslinking structure, the second material is the same as the first material, and the quantum dots are connected by the connecting structures through the crosslinking structure.

### BRIEF DESCRIPTION OF THE DRAWINGS

In order to explain technical solutions in embodiments of the disclosure more clearly, the following will briefly introduce the drawings needed to be used in description of the embodiments. Apparently, the drawings in the following description are only some embodiments of the disclosure. For ordinary skilled in the art, other drawings can be obtained from these drawings without paying creative effort.

In order to understand the disclosure and beneficial effects thereof more completely, the following will be described in combination with the drawings. In the following description, the same reference numerals indicate the same elements.

FIGS. 1A to 1D are schematic structural diagrams of a manufacturing process for a display panel according to some embodiments of the disclosure;

FIG. 2 is a schematic structural diagram of a display panel according to some embodiments of the disclosure;

FIG. 3 is a schematic structural diagram of connecting quantum dots according to some embodiments of the disclosure;

FIG. 4 is another schematic structural diagram of a display panel according to some embodiments of the disclosure;

FIG. 5 is a flowchart of a method for manufacturing a display panel according to some embodiments of the disclosure; and

FIGS. 6 to 10 are schematic structural diagrams of a manufacturing process of a display panel according to some embodiments of the disclosure.

### REFERENCE CHARACTERS

1, substrate; 2, anode; 3, pixel definition layer; 4, light-emitting material layer; 5, light-emitting layer; and 6, residual material;
10, first electrode layer; and 11, first electrode;
20, auxiliary layer; 21, auxiliary portion; 211, first auxiliary portion; 212, second auxiliary portion; 213, third auxiliary portion; and 210, auxiliary portion to be etched;
30, light-emitting layer; 31, light-emitting portion; 311, first light-emitting portion; 312, second light-emitting portion; 313, third light-emitting portion; 310, light-emitting material layer; 32, quantum dot; 321, quantum dot body; 322, connecting group; 33, connecting structure; 331, crosslinking structure; and 3101, light-emitting portion to be etched; and
40, second electrode layer; 50, array substrate; 60, pixel definition layer; 70, first functional layer; and 80, mask.

### DETAILED DESCRIPTION

The following will provide a clear and complete description of the technical solutions in the embodiments of the disclosure, in conjunction with the drawings. Apparently, the described embodiments are only a part of the embodiments of the disclosure, not all of them. Based on the embodiments of the disclosure, all other embodiments obtained by those skilled in the art without creative labor are within the scope of protection of the disclosure.

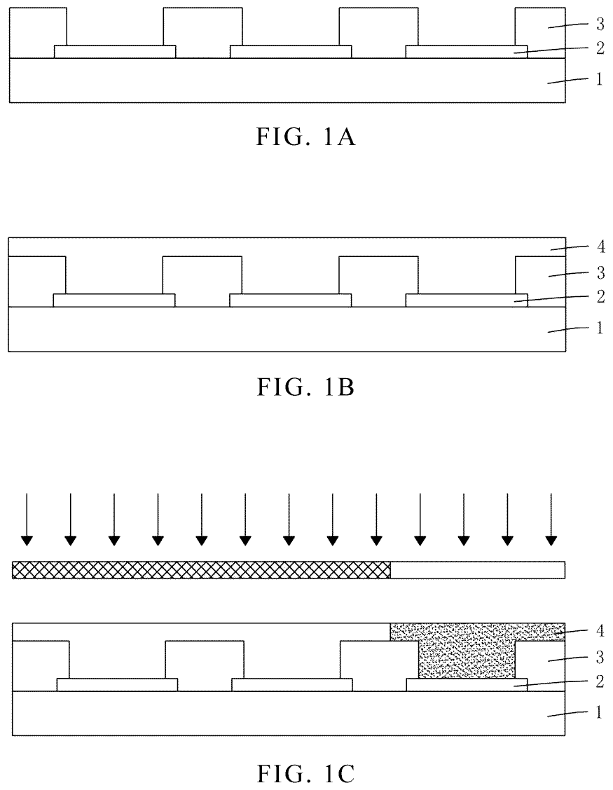

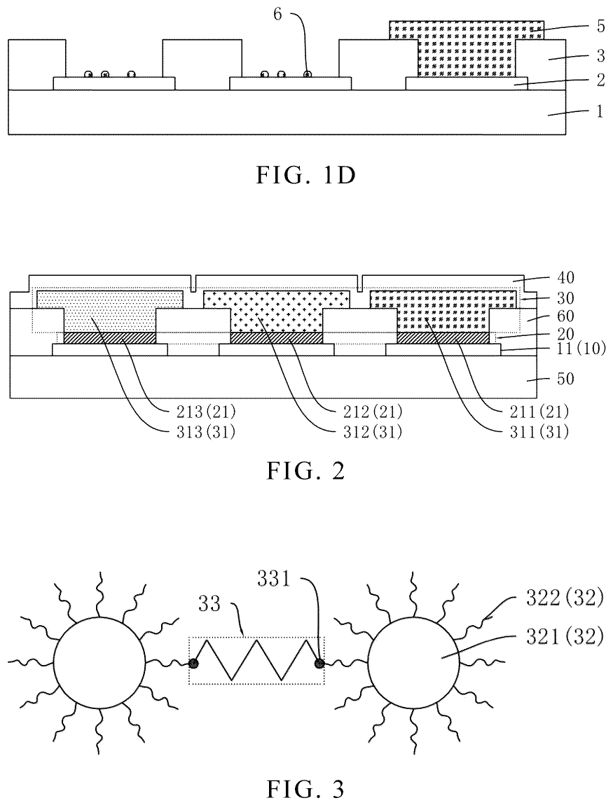

Referring to FIGS. 1A to 1D, a method for manufacturing a quantum dot light-emitting display panel in related art includes the following steps:
providing a substrate 1, in which the substrate 1 includes a base and a thin film transistor layer disposed on the base;
forming a plurality of anodes 2 on the substrate 1;
forming a pixel definition layer 3 on the substrate 1, in which the pixel definition layer 3 is provided with a plurality of pixel openings, and each of the pixel openings exposes a surface of one of the anodes 2;
forming a quantum dot material layer 4 on the pixel definition layer 3; and
patterning the quantum dot material layer 4 by using a mask to form a light-emitting layer 5 in a preset pixel opening.

A functional film layer such as a hole transport layer or an electron blocking layer is formed between the anodes 2 and the light-emitting layer 5. The quantum dot material layer 4 may undergo a crosslinking reaction during the film formation process, and the quantum dot material layer 4 is cross-linked with the functional film layer such as the hole transport layer or the electron blocking layer, which may increase an adhesion force between the quantum dot material layer 4 and the functional film layer such as the hole transport layer or the electron blocking layer. Therefore, during the process of removing the quantum dot material layer 4, a residual material 6 of the quantum dot material layer 4 forms in the non-preset pixel opening. Since the color of light emitted by the light-emitting layer 5 formed in the preset pixel opening is different from the color of light emitted by the light-emitting layer to be formed in the non-preset pixel opening, the residual material 6 affects the luminescence of the light-emitting layer to be formed in the non-preset pixel opening, which may affect the color gamut and the display effect of the display panel.

Referring to FIG. 2 and FIG. 3, some embodiments of the disclosure provide a display panel, which includes a first electrode layer 10, an auxiliary layer 20, a light-emitting layer 30, and a second electrode layer 40.

The first electrode layer 10 includes a plurality of first electrodes 11. The auxiliary layer 20 is disposed on a side of the first electrode layer 10, and the auxiliary layer 20 includes a plurality of auxiliary portions 21 disposed corresponding to the plurality of first electrodes 11 respectively. Each of the auxiliary portions 21 is disposed on a side of one of the first electrodes 11. The light-emitting layer 30 is disposed on a side of the auxiliary layer 20 away from the first electrode layer 10, and the light-emitting layer 30 includes a plurality of light-emitting portions 31 disposed corresponding to the plurality of auxiliary portions 21 respectively. Each of the light-emitting portions 31 is disposed on a side of one of the auxiliary portions 21 away from corresponding one of the first electrodes 11. The second electrode layer 40 is disposed on a side of the light-emitting layer 30 away from the auxiliary layer 20.

The auxiliary portion 21 includes a first material. The light-emitting portion 31 includes quantum dots 32 and connecting structures 33 connected between the quantum dots 32. The connecting structure 33 is formed by a second material substituted by a crosslinking structure 331, the second material is the same as the first material, and the quantum dots 32 are connected by the connecting structure 33 through the crosslinking structure 331.

In the embodiments of the disclosure, the auxiliary portion 21 is provided between the light-emitting portion 31 and the first electrode 11, and the first material in the auxiliary portion 21 is not provided with the crosslinking structure 331 compared with the light-emitting portion 31. Therefore, the first material in the auxiliary portion 21 does not undergo crosslinking, and the first material is not cross-linked with a film layer disposed on a side of the auxiliary portion 21 away from the light-emitting portion 31, which reduce the adhesion force between the auxiliary portion 21 and the film layer disposed on a side of the auxiliary portion 21 away from the light-emitting portion 31. Moreover, since the auxiliary portion 21 is disposed between the light-emitting portion 31 and the first electrode 11, when removing the light-emitting portion located in the same layer as the light-emitting portion 31 in the non-preset areas during the patterning process of forming the light-emitting layer 30, the auxiliary portion located in the same layer as the auxiliary portion 21 in the non-preset areas can be removed, thereby improving the phenomenon of residual of the material of the light-emitting layer 30 in the non-preset areas during the patterning process, improving the color gamut of the display panel, and enhancing the display effect of the display panel.

In some embodiments of the disclosure, the first material is selected from at least one of the following compounds:

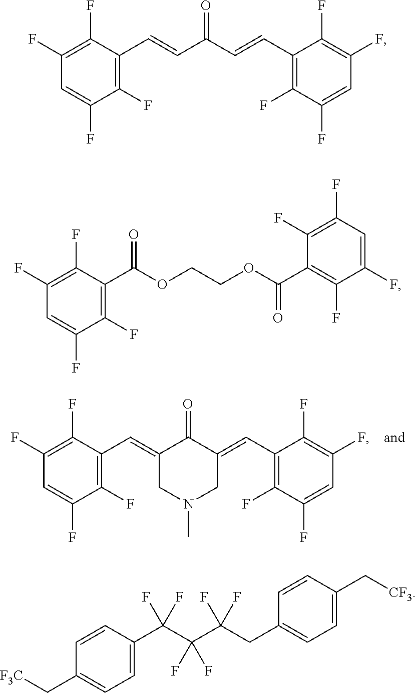

In some embodiments of the disclosure, the connecting structure includes at least one of structures represented by the following formulae:

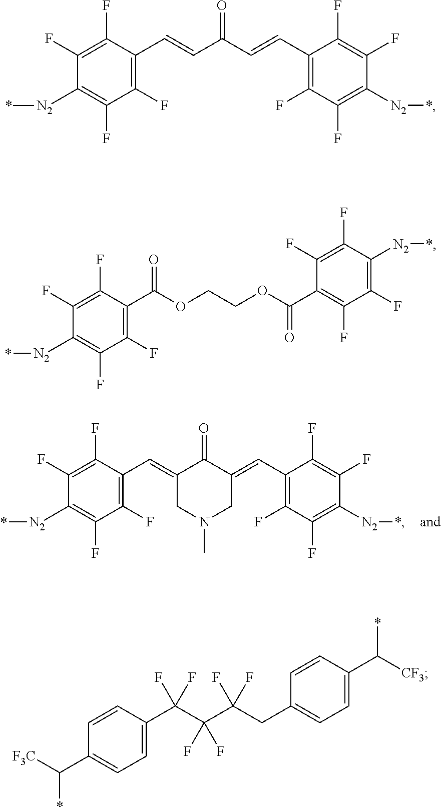

in which * indicates a linking site.

In some embodiments of the disclosure, the crosslinking structure is —N₂—.

In some embodiments of the disclosure, one or more hydrogen atoms in the second material are substituted by the crosslinking structure to form the connecting structures.

In some embodiments of the disclosure, the light-emitting portions include a first light-emitting portion, a second light-emitting portion, and a third light-emitting portion; the quantum dots in the first light-emitting portion, the quantum dots in the second light-emitting portion, and the quantum dots in the third light-emitting portion are independently selected from one of red quantum dots, green quantum dots, and blue quantum dots; and the quantum dots in the first light-emitting portion, the quantum dots in the second light-emitting portion, and the quantum dots in the third light-emitting portion are different from each other; and
the auxiliary portions include a first auxiliary portion disposed between one of the first electrodes and the first light-emitting portion, a second auxiliary portion disposed between one of the first electrodes and the second light-emitting portion, and a third auxiliary portion disposed between one of the first electrodes and the third light-emitting portion; and the first material in the first auxiliary portion, the first material in the second auxiliary portion, and the first material in the third auxiliary portion are the same or different.

In some embodiments of the disclosure, each of the quantum dots includes a quantum dot body and a connecting group connected to the quantum dot body, and the quantum dot body is connected to the crosslinking structure through the connecting group; and the connecting group is selected from a substituted or unsubstituted alkyl group having 1 to 4 carbon atoms.

In some embodiments of the disclosure, the first material includes a substituted or unsubstituted alkyl group having 1 to 4 carbon atoms.

In some embodiments of the disclosure, the display panel further includes a first functional layer disposed between the auxiliary portion and the first electrode, and an adhesion force between the auxiliary portion and the first functional layer is less than an adhesion force between the auxiliary portion and the light-emitting portion.

Referring to FIG. 2 and FIG. 3, the display panel further includes an array substrate 50 and a pixel definition layer 60, the first electrode layer 10 is disposed on the array substrate 50, and the pixel definition layer 60 is disposed on the first electrode layer 10.

In some embodiments, the array substrate 50 includes a substrate and a thin film transistor layer disposed on the substrate. The thin film transistor layer is disposed on a side of the substrate close to the first electrode layer 10. For example, the substrate is a hard substrate, such as a glass substrate; alternatively, the substrate is a flexible substrate, such as a substrate made from polyimide. When the substrate is a flexible substrate, the substrate is composed of a plurality of sub-substrates made from the same material, such as polyimide; and adjacent two sub-substrates are bonded together through an adhesive sub-layer.

In some embodiments, the thin film transistor layer includes a plurality of thin film transistors, each thin film transistor includes a semiconductor disposed on the substrate, and the semiconductor is made from polysilicon or a metal oxide such as an indium gallium zinc oxide. The semiconductor is divided into a channel area and a source area and a drain area formed at two sides of the channel area. The thin film transistor layer further includes a first gate insulating layer covering the semiconductor. The thin film transistor further includes a first gate disposed on the first gate insulating layer, and the first gate overlaps with the channel area. The first gate is provided as multiple layers or a single layer including a low resistance material such as Al, Ti, Mo, Cu, Ni, or an alloy thereof, or a material having high anti-corrosion property. The thin film transistor layer further includes a second gate insulating layer covering the first gate. The thin film transistor further includes a second gate disposed on the second gate insulating layer, and the second gate overlaps with the first gate. The second gate is provided as multiple layers or a single layer including a low-resistance material such as Al, Ti, Mo, Cu, Ni, or an alloy thereof, or a material having high anti-corrosion property. The thin film transistor layer further includes a first interlayer insulating layer disposed on the second gate. The first interlayer insulating layer, the first gate insulating layer, and the second gate insulating layer are provided with a source contact hole and a drain contact hole, and the source area and the drain area are exposed through the source contact hole and the drain contact hole, respectively.

The thin film transistor further includes a source and a drain disposed in the same layer and located on the first interlayer insulating layer. The source is connected to the source area passing through the source contact hole, and the drain is connected to the drain area passing through the drain contact hole. Both of the source and the drain are provided as multiple layers or single layers made from a low-resistance material such as Al, Ti, Mo, Cu, Ni, or an alloy thereof, or a material having a high anti-corrosion property. For example, both of the source and the drain are composed of three layers of Ti/Cu/Ti, Ti/Ag/Ti, Ti/Al/Ti, or Mo/Al/Mo, single layers, or multiple layers.

In some embodiments, the array substrate 50 further includes a planarization layer disposed between the thin film transistor layer and the first electrode layer 10, and the planarization layer covers the source and the drain.

In some embodiments, the pixel definition layer 60 is disposed on the planarization layer and the first electrode layer 10, the pixel definition layer 60 is provided with a plurality of pixel openings, each of the plurality of pixel openings is disposed corresponding to one of the plurality of first electrodes 11, and each of the pixel openings exposes a surface of one of the first electrodes 11.

In some embodiments, the plurality of auxiliary portions 21 of the auxiliary layer 20 are correspondingly disposed in the plurality of pixel openings. For example, each of the auxiliary portions 21 is disposed in one of the pixel openings, and each of the auxiliary portions 21 is disposed on a side of corresponding one of the first electrodes 11 away from the array substrate 50.

In some embodiments, the plurality of the light-emitting portions 31 of the light-emitting layer 30 are disposed corresponding to the plurality of pixel openings respectively. For example, each of the light-emitting portions 31 is disposed in one of the pixel openings; or, a part of each of the light-emitting portions 31 is disposed in one of the pixel openings, and another part of the each of the light-emitting portions 31 extends outside the one of the pixel openings and is disposed on a side of the pixel definition layer 60 away from the array substrate 50. Each of the light-emitting portions 31 is disposed on a side of one of the auxiliary portions 21 away from corresponding one of the first electrodes 11.

The second electrode layer 40 is disposed on a side of the light-emitting layer 30 away from the auxiliary layer 20, and the second electrode layer 40 covers the plurality of light-emitting portions 31 and the pixel definition layer 60.

It should be noted that the light-emitting layer 30 provided in the embodiments of the disclosure is a quantum dot light-emitting layer, the first electrode layer 10 is an anode, and the second electrode layer 40 is a cathode. Holes provided by the first electrode layer 10 and electrons provided by the second electrode layer 40 meet in the light-emitting layer 30 to form photons, so that the light-emitting layer 30 can emit light by recombination of the photons.

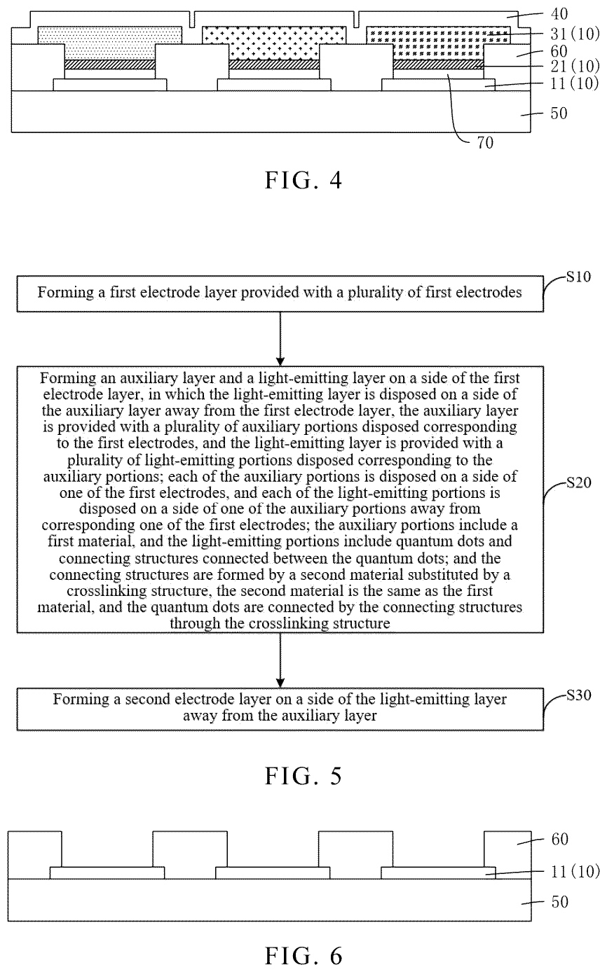

In some embodiments, referring to FIGS. 2 to 4, the display panel illustrated in FIG. 4 is different from the display panel illustrated in FIG. 2 in that the display panel further includes a first functional layer 70 disposed between the auxiliary layer 20 and the first electrode layer 10, and the first functional layer 70 includes at least one of a hole injection layer, a hole transport layer, and an electron blocking layer.

For example, the first functional layer 70 includes the hole injection layer and the hole transport layer, the hole transport layer is disposed between the hole injection layer and the auxiliary layer 20, and the auxiliary layer 20 is disposed on a side of the hole transport layer away from the hole injection layer.

Alternatively, the first functional layer 70 includes the hole injection layer, the hole transport layer, and the electron blocking layer, the hole transport layer is disposed on a side of the hole injection layer away from the first electrode layer 10, the electron blocking layer is disposed on a side of the hole transport layer away from the first electrode layer 10, and the auxiliary layer 20 is disposed on a side of the electron blocking layer away from the hole transport layer.

Alternatively, the first functional layer 70 includes the hole transport layer and the electron blocking layer, the electron blocking layer is disposed on a side of the hole transport layer away from the first electrode layer 10, and the auxiliary layer 20 is disposed on a side of the electron blocking layer away from the hole transport layer.

In some embodiments, the first functional layer 70 is disposed at least between the auxiliary portion 21 and the first electrode 11, that is, the first functional layer 70 is disposed in the pixel opening and between the auxiliary portion 21 and the first electrode 11. Alternatively, the first functional layer 70 covers an entire surface of the pixel definition layer 60 and extends into the pixel opening, and the first functional layer 70 located in the pixel opening is disposed between the auxiliary portion 21 and the first electrode 11.

It can be understood that, in some embodiments, the display panel further includes a second functional layer disposed between the light-emitting layer 30 and the second electrode layer 40, and the second functional layer includes at least one of a hole blocking layer, an electron transport layer, and an electron injection layer. When the second functional layer includes the hole blocking layer, the electron transport layer, and the electron injection layer, the hole blocking layer is disposed on a side of the light-emitting layer 30 away from the auxiliary layer 20, the electron transport layer is disposed on a side of the electron blocking layer 30 away from the hole blocking layer, and the electron injection layer is disposed on a side of the electron transport layer away from the hole blocking layer.

In some embodiments of the disclosure, the auxiliary portion 21 is disposed on a surface of the first functional layer 70 away from the array substrate 50, and the light-emitting portion 31 is disposed on a surface of the auxiliary portion 21 away from the first functional layer 70.

The auxiliary portion 21 includes the first material, the light-emitting portion 31 includes the quantum dots 32 and the connecting structures 33 connected between the quantum dots 32, the connecting structure 33 is formed by a second material substituted by a crosslinking structure 331, the second material is the same as the first material, and the quantum dots 32 are connected by the connecting structure 33 through the crosslinking structure 331. Therefore, the first material in the auxiliary portion 21 does not undergo crosslinking, and the first material is not cross-linked with a film layer disposed on a side of the auxiliary portion 21 away from the light-emitting portion 31, which reduce the adhesion force between the auxiliary portion 21 and the film layer disposed on a side of the auxiliary portion 21 away from the light-emitting portion 31, improve the phenomenon of residual of the material of the light-emitting layer 30 in the non-preset areas during the patterning process, improve the color gamut of the display panel, and enhance the display effect of the display panel.

In some embodiments, an adhesion force between the auxiliary portion 21 and the first functional layer 70 is less than an adhesion force between the auxiliary portion 21 and the light-emitting portion 31, which facilitates the peeling of the auxiliary portion 21 from the first functional layer 70, and improves the phenomenon of residual of the material of the light-emitting layer 30 during the patterning process.

In some embodiments, the light-emitting portions 31 include a first light-emitting portion 311, a second light-emitting portion 312, and a third light-emitting portion 313; the quantum dots in the first light-emitting portion 311, the quantum dots in the second light-emitting portion 312, and the quantum dots in the third light-emitting portion 313 are independently selected from one of red quantum dots, green quantum dots, and blue quantum dots; and the quantum dots in the first light-emitting portion 311, the quantum dots in the second light-emitting portion 312, and the quantum dots in the third light-emitting portion 313 are different from each other.

It should be noted that the first light-emitting portion 311, the second light-emitting portion 312, and the third light-emitting portion 313 are selected from the quantum dots of different colors. For example, the first light-emitting portion 311 is selected from red quantum dots, the second light-emitting portion 312 is selected from green quantum dots, and the third light-emitting portion 313 is selected from blue quantum dots, so as to achieve full-color display of the display panel.

The auxiliary portions 21 include a first auxiliary portion 211 disposed between one of the first electrodes 11 and the first light-emitting portion 311, a second auxiliary portion 212 disposed between one of the first electrodes 11 and the second light-emitting portion 312, and a third auxiliary portion 213 disposed between one of the first electrodes 11 and the third light-emitting portion 313. The first material in the first auxiliary portion 211, the first material in the second auxiliary portion 212, and the first material in the third auxiliary portion 213 are the same or different.

In some embodiments of the disclosure, during the process for preparing the first light-emitting portion 311, an auxiliary material layer is first formed in each pixel opening. For example, as illustrated in FIGS. 6 to 10, a first auxiliary portion 211 is formed in a preset pixel opening corresponding to the first light-emitting portion 311, an auxiliary portion to be etched 210 is formed in a non-preset pixel opening, and the auxiliary portion to be etched 210 and the first auxiliary portion 211 are formed by the same process. Then, a first light-emitting material layer is formed on the pixel definition layer 60 and the auxiliary material layer, the first light-emitting material layer located in the preset pixel opening is disposed on the first auxiliary portion 211, and the first light-emitting material layer located in the non-preset pixel opening is disposed on the auxiliary portion to be etched 210. Since the first light-emitting material layer includes the quantum dots 32 and the connecting structures 33 connected between the quantum dots 32, the first light-emitting material layer may undergo a crosslinking reaction during the film formation process. Subsequently, the first light-emitting material layer is patterned to remove the first light-emitting material layer and the auxiliary portion to be etched 210 in the non-preset pixel opening, so that the first light-emitting portion 311 is formed in the preset pixel opening. Since the first material in the auxiliary portion to be etched 210 does not undergo crosslinking, and the first material is not cross-linked with the first functional layer 70, the adhesion force between the auxiliary portion 21 and the first functional layer 70 can be reduced, the phenomenon of residual of the first light-emitting material layer in the non-preset areas during the patterning process can be improved, the color gamut of the display panel can be improved, and the display effect of the display panel can be enhanced.

It can be understood that the subsequent preparation processes for preparing the second light-emitting portion 312 and the third light-emitting portion 313 are performed with reference to the preparation process of the first light-emitting portion 311, therefore, the phenomenon of residual of the material of the second light-emitting portion 312 and the material of the third light-emitting portion 313 in the non-preset pixel openings can be improved, so as to improve the color gamut of the display panel and enhance the display effect of the display panel.

In some embodiments, the first material is selected from at least one of the following compounds:

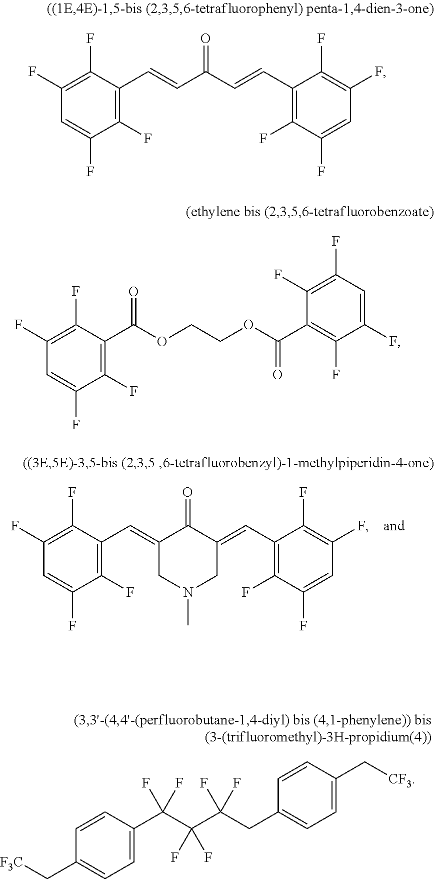

In some embodiments, the connecting structure 33 includes at least one of structures represented by the following formulae:

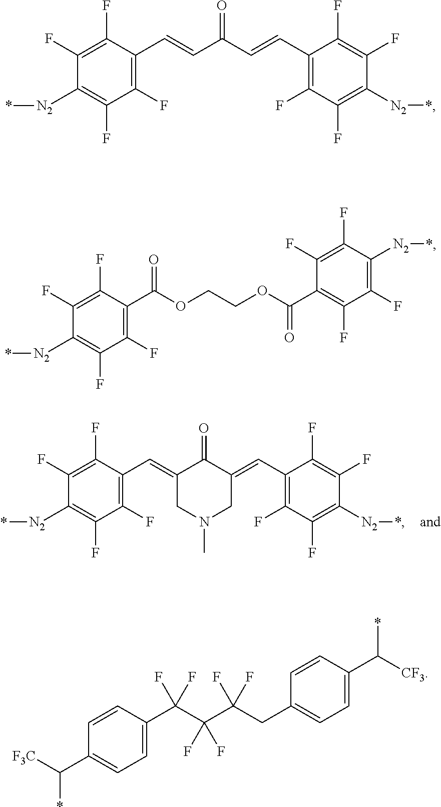

* indicates a linking site. The crosslinking structure 331 is formed by the crosslinking of at least one unsaturated bond of an azide group, a bisacridinyl group, a carbon-carbon double bond, and a carbon-carbon triple bond. The first material is not provided with the crosslinking structure 331 compared with the connecting structure 33, so that crosslinking does not occur during the formation process of the auxiliary portion 21, and crosslinking also does not occur between the auxiliary portion 21 and the first functional layer 70, the auxiliary portion located in the non-preset pixel opening can be removed during the patterning process, thereby reducing the residual of the material of the auxiliary portion in the non-preset areas.

It should be noted that the auxiliary portion 21 does not include the quantum dots 32. When the auxiliary portion 21 includes the quantum dots 32, a thickness of a film layer including the quantum dots 32 stacked on the display panel may increase, resulting in the increasing of the driving voltage of the display panel. Therefore, in the embodiments of the disclosure, the auxiliary portion 21 does not include the quantum dots 32, so as to ensure an appropriate or smaller driving voltage of the display panel.

In some embodiments, one or more hydrogen atoms in the first material are substituted by the crosslinking structure 331 to form the connecting structure 33. For example, hydrogen atoms on two sides of a benzene ring of the first material are substituted by the crosslinking structure 331, or, hydrogen atoms on two sides of an alkyl group of the first material are substituted by the crosslinking structure 331.

In some implementations, each of the quantum dots 32 includes a quantum dot body 321 and a connecting group 322 connected to the quantum dot body 321, and the connecting group 322 is selected from a substituted or unsubstituted alkyl group having 1 to 4 carbon atoms. The quantum dot body 321 is connected to the crosslinking structure 331 through the connecting group 322. The connecting group 322 can modify the quantum dot body 321, so as to improve the distribution uniformity and crosslinking uniformity of the quantum dots 32 in the light-emitting layer 30. The quantum dots 32 are connected to the connecting structure 33 through the connecting group 322. A substituent group in the connecting group 322 is the same as the crosslinking structure 331, which is formed by the crosslinking of at least one unsaturated bond of an azide group, a bisacridinyl group, a carbon-carbon double bond, and a carbon-carbon triple bond.

In some embodiments, the first material includes a substituted or unsubstituted alkyl group having 1 to 4 carbon atoms. In some embodiments, a substituent group in the first material includes an amino group. It can be understood that in the manufacturing process, the material of the auxiliary layer 20 is considered to be obtained by removing the quantum dots 32 and a crosslinking group from the material of the light-emitting layer 30.

In the embodiments of the disclosure, the auxiliary portion 21 is provided between the light-emitting portion 31 and the first electrode 11, and the first material in the auxiliary portion 21 is not provided with the crosslinking structure 331 compared with the light-emitting portion 31. Therefore, the first material in the auxiliary portion 21 does not undergo crosslinking, and the first material is not cross-linked with a film layer disposed on a side of the auxiliary portion 21 away from the light-emitting portion 31, which reduce the adhesion force between the auxiliary portion 21 and the film layer disposed on a side of the auxiliary portion 21 away from the light-emitting portion 31. Moreover, since the auxiliary portion 21 is disposed between the light-emitting portion 31 and the first electrode 11, when removing the light-emitting portion located in the same layer as the light-emitting portion 31 in the non-preset areas during the patterning process of forming the light-emitting layer 30, the auxiliary portion located in the same layer as the auxiliary portion 21 in the non-preset areas can be removed, thereby improving the phenomenon of residual of the material of the light-emitting layer 30 in the non-preset areas during the patterning process, improving the color gamut of the display panel, and enhancing the display effect of the display panel.

Furthermore, some embodiments of the disclosure further provide a method for manufacturing a display panel. Referring to FIGS. 2 to 5 and 6 to 10, the method for manufacturing the display panel includes the steps as follows.

Step S10, forming the first electrode layer 10 including the plurality of first electrodes 11.

Step S20, forming the auxiliary layer 20 and the light-emitting layer 30 on a side of the first electrode layer 10. The light-emitting layer 30 is disposed on a side of the auxiliary layer 20 away from the first electrode layer. The auxiliary layer 20 includes the plurality of auxiliary portions 21 disposed corresponding to the plurality of first electrodes 11 respectively, the light-emitting layer 30 includes the plurality of light-emitting portions 31 disposed corresponding to the plurality of auxiliary portions 21 respectively, each of the auxiliary portions 21 is disposed on a side of one of the first electrodes 11, and each of the light-emitting portions 31 is disposed on a side of one of the auxiliary portions 21 away from corresponding one of the first electrodes 11. The auxiliary portion 21 includes the first material. The light-emitting portion 31 includes the quantum dots 32 and the connecting structures 33 connected between the quantum dots 32. The connecting structure 33 is formed by a second material substituted by a crosslinking structure 331, the second material is the same as the first material, and the quantum dots 32 are connected by the connecting structure 33 through the crosslinking structure 331.

Step S30, forming the second electrode layer 40 on a side of the light-emitting layer 30 away from the auxiliary layer 20.

In some embodiments of the disclosure, the step of forming the auxiliary layer and the light-emitting layer on a side of the first electrode layer includes:
forming an auxiliary material layer including a plurality of auxiliary portions and a plurality of auxiliary portions to be etched by using the first material selected from at least one of the following compounds:

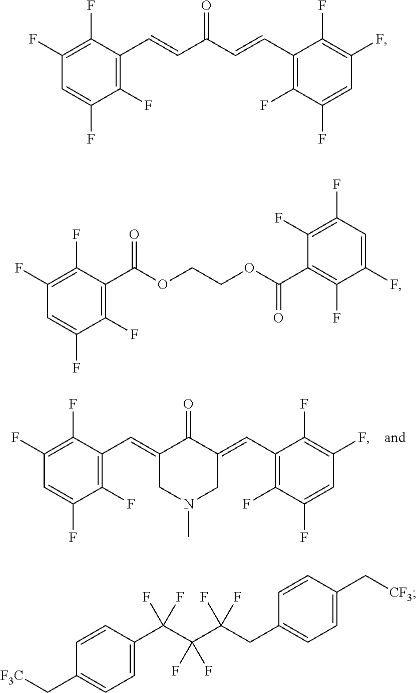

forming a first light-emitting material layer on a side of the auxiliary material layer away from the first electrode layer;
etching the first light-emitting material layer to form the light-emitting portions and a plurality of light-emitting portions to be etched, in which each of the auxiliary portions is disposed between one of the light-emitting portions and corresponding one of the first electrodes, and each of the auxiliary portions to be etched is disposed between one of the light-emitting portions to be etched and corresponding one of the first electrodes; and
removing the light-emitting portions to be etched and the auxiliary portions to be etched.

In some embodiments of the disclosure, the step of forming the first light-emitting material layer on a side of the auxiliary material layer away from the first electrode layer includes:
providing quantum dots and a crosslinking material; and
forming the quantum dots and the connecting structures connected between the quantum dots by reaction of the quantum dots and the crosslinking material, in which the crosslinking material includes the first material substituted by a crosslinking group, and the crosslinking group is selected from at least one of an azide group, a bisacridinyl group, a carbon-carbon double bond, and a carbon-carbon triple bond.

In some embodiments of the disclosure, the crosslinking material is selected from at least one of the following compounds:

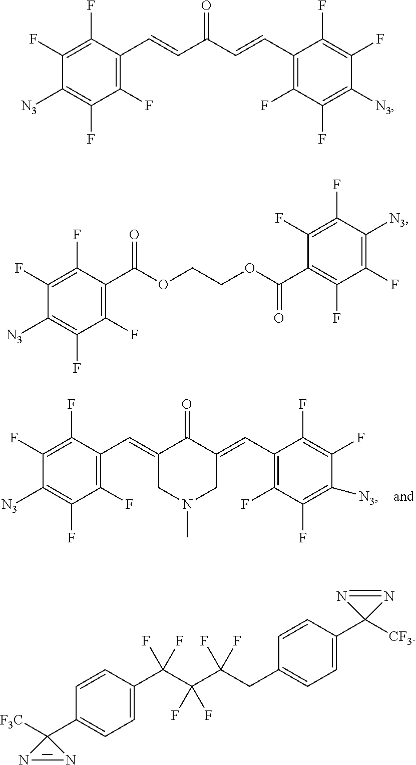

In step S10, the array substrate 50 is first provided.

Subsequently, the first electrode layer 10 including the plurality of first electrodes 11 is formed on the array substrate 50.

In step S20, the pixel definition layer 60 provided with the plurality of pixel openings is formed on the array substrate 50, and each pixel opening corresponds to one first electrode 11 to expose a surface of the first electrode 11, as illustrated in FIG. 6.

In some embodiments, the display panel further includes the first functional layer 70 disposed in the pixel opening, and the first functional layer 70 is disposed on a side of the first electrode layer 10 away from the array substrate 50. The first functional layer 70 includes at least one of a hole injection layer, a hole transport layer, and an electron blocking layer.

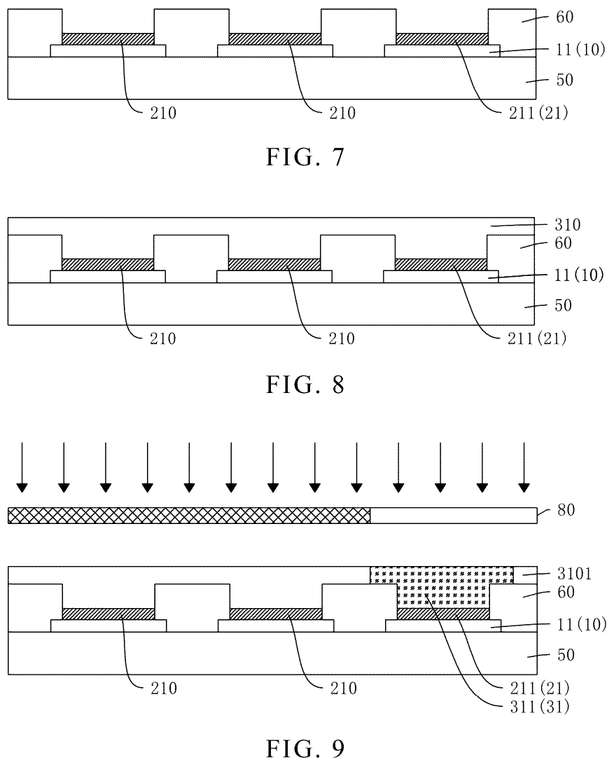

Subsequently, the auxiliary material layer is formed in the pixel opening. The auxiliary material layer includes a first auxiliary portion 211 disposed in a preset pixel opening and an auxiliary portion to be etched 210 disposed in a non-preset pixel opening, as illustrated in FIG. 7.

In some embodiments, the first functional layer 70 includes the hole injection layer and the hole transport layer, the hole transport layer is disposed between the hole injection layer and the auxiliary layer 20, and the auxiliary material layer is disposed on a side of the hole transport layer away from the hole injection layer.

In some embodiments, the first functional layer 70 includes the hole injection layer, the hole transport layer, and the electron blocking layer. The hole transport layer is disposed on a side of the hole injection layer away from the first electrode layer 10, the electron blocking layer is disposed on a side of the hole transport layer away from the first electrode layer 10, and the auxiliary material layer is disposed on a side of the electron blocking layer away from the hole transport layer.

In some embodiments, the first functional layer 70 includes the hole transport layer and the electron blocking layer, the electron blocking layer is disposed on a side of the hole transport layer away from the first electrode layer 10, and the auxiliary material layer is disposed on a side of the electron blocking layer away from the hole transport layer.

In some embodiments, the first functional layer 70 is disposed at least between the auxiliary material layer and the first electrode 11, that is, the first functional layer 70 is disposed in the pixel opening and between the auxiliary portion 21 and the first electrode 11. Alternatively, the first functional layer 70 covers the entire surface of the pixel definition layer 60 and extends into the pixel opening, and the first functional layer 70 located in the pixel opening is disposed between the auxiliary material layer and the first electrode 11.

The auxiliary material layer is made from the first material that is selected from at least one of the following compounds:

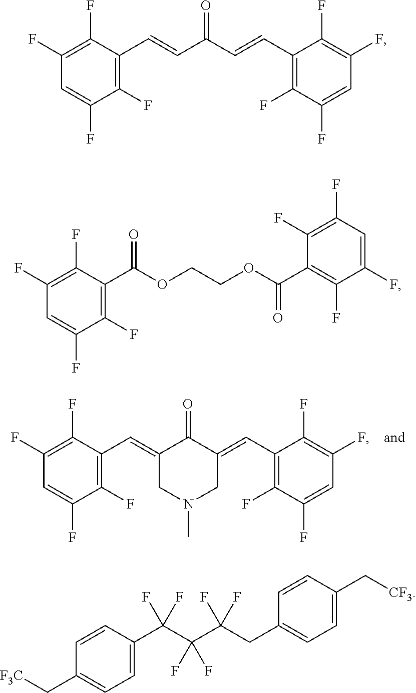

A first light-emitting material layer 310 is formed on a side of the auxiliary material layer away from the first electrode layer 10, as illustrated in FIG. 8.

The quantum dots 32 and the connecting structures 33 connected between the quantum dots 32 are formed by the reaction of the quantum dots 32 and the crosslinking material. The crosslinking material includes the first material substituted by a crosslinking group. The crosslinking group is selected from at least one of an azide group, a bisacridinyl group, a carbon-carbon double bond, and a carbon-carbon triple bond.

In some embodiments, the crosslinking material is selected from at least one of the following compounds:

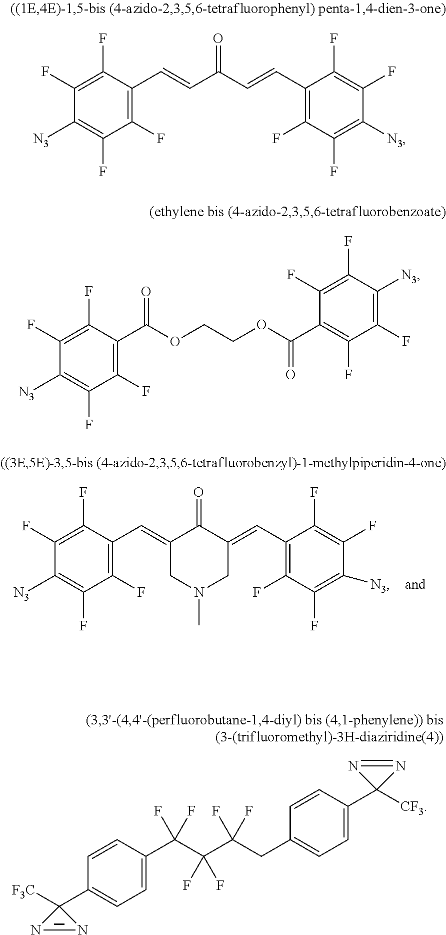

The first light-emitting material layer 310 is performed on light treatment using a mask 80. The first light-emitting material layer 310 corresponding to a first area of the mask 80 forms the first light-emitting portion 311 after the light treatment, and the first light-emitting material layer 310 corresponding to a second area of the mask 80 forms the light-emitting portion to be etched 3101 after the light treatment. The auxiliary material layer includes the first auxiliary portion 211 disposed between the first light-emitting portion 311 and one first electrode 11, and includes the auxiliary portion to be etched 210 disposed between the light-emitting portion to be etched 3101 and one first electrode 11, and the auxiliary portion to be etched 210 is disposed in the non-preset pixel opening, as illustrated in FIG. 9.

Transmittance of the first area and transmittance of the second area of the mask 80 are different. For example, the transmittance of the first area is greater than the transmittance of the second area, or, the first area is transparent and the second area is opaque.

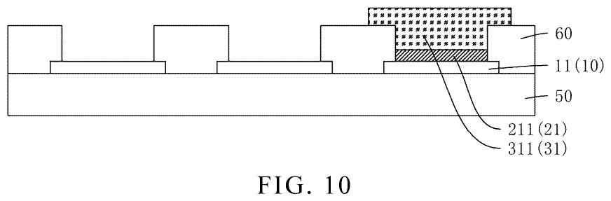

Subsequently, the light-emitting portion to be etched 3101 and the auxiliary portion to be etched 210 are removed to form the first auxiliary portion 211 disposed in the preset pixel opening and the first light-emitting portion 311 disposed on a side of the first auxiliary portion 211 away from the first electrode 11, as illustrated in FIG. 10.

It should be noted that the first light-emitting material layer 310 is disposed on the auxiliary portion to be etched 210 in the non-preset pixel opening. The first light-emitting material layer 310 includes the quantum dots 32 and the connecting structures 33 connected between the quantum dots 32, and therefore the first light-emitting material layer 310 undergoes a crosslinking reaction during the film formation process. The first material in the auxiliary portion to be etched 210 does not undergo crosslinking, and the first material is not cross-linked with the first functional layer 70, which can reduce the adhesion force between the auxiliary portion to be etched 210 and the first functional layer 70, improve the phenomenon of residual of the material of the first light-emitting material layer 310 in the non-preset areas during the patterning process, improve the color gamut of the display panel, and enhance the display effect of the display panel.

In some embodiments, during the process of removing the light-emitting portion to be etched 3101 and the auxiliary portion to be etched 210, ultrasonic cleaning (USC) is used in combination with development to further reduce the risk of residual of the material of the first light-emitting material layer 310.

It can be understood that the subsequent preparation processes of the second light-emitting portion 312 and the third light-emitting portion 313 can be performed with reference to the preparation process of the first light-emitting portion 311. For example, an auxiliary material layer is formed, a second light-emitting material layer or a third light-emitting material layer is formed on the auxiliary material layer, and then the second light-emitting material layer and the third light-emitting material layer in the non-preset pixel opening are removed together with the auxiliary material layer, so as to improve the residual of materials of the second light-emitting material layer and the third light-emitting material layer in the non-preset pixel opening, thereby improving the color gamut of the display panel and enhancing the display effect of the display panel.

The second light-emitting portion 312 and the third light-emitting portion 313 are sequentially formed with reference to the above-mentioned processes, the second auxiliary portion 212 is formed between the second light-emitting portion 312 and the first electrode 11, and the third auxiliary portion 213 is formed between the third light-emitting portion 313 and the first electrode 11. The first light-emitting portion 311, the second light-emitting portion 312, and the third light-emitting portion 313 constitute the light-emitting layer 30, and the first auxiliary portion 211, the second auxiliary portion 212, and the third auxiliary portion 213 constitute the auxiliary layer 20.

In step S30, the second electrode layer 40 is formed on a side of the light-emitting layer 30 away from the auxiliary layer 20, and the second electrode layer 40 covers the pixel definition layer 60 and the plurality of light-emitting portions 31.

In the embodiments of the disclosure, the auxiliary portion 21 is provided between the light-emitting portion 31 and the first electrode 11, and the first material in the auxiliary portion 21 is not provided with the crosslinking structure 331 compared with the light-emitting portion 31. Therefore, the first material in the auxiliary portion 21 does not undergo crosslinking, and the first material is not cross-linked with a film layer disposed on a side of the auxiliary portion 21 away from the light-emitting portion 31, which reduce the adhesion force between the auxiliary portion 21 and the film layer disposed on a side of the auxiliary portion 21 away from the light-emitting portion 31. Moreover, since the auxiliary portion 21 is disposed between the light-emitting portion 31 and the first electrode 11, when removing the light-emitting portion located in the same layer as the light-emitting portion 31 in the non-preset areas during the patterning process of forming the light-emitting layer 30, the auxiliary portion located in the same layer as the auxiliary portion 21 in the non-preset areas can be removed, thereby improving the phenomenon of residual of the material of the light-emitting layer 30 in the non-preset areas during the patterning process, improving the color gamut of the display panel, and enhancing the display effect of the display panel.

Some embodiments of the disclosure further provide a display device, the display device includes the display panel as described in any one of the above-mentioned embodiments, or the display device is prepared by using the method for manufacturing the display panel as described in any one of the above-mentioned embodiments.

It can be understood that since the display device provided by the embodiments of the disclosure includes the same display panel as described in any one of the above-mentioned embodiments, the display device has the same beneficial effects as the display panel as described in any one of the above-mentioned embodiments, and will not be repeated herein.

In the disclosure, the terms “first” and “second” are used only for the purpose of description, and cannot be understood as indicating or implying relative importance or implying the number of features indicated. Therefore, the features limited to “first” and “second” may explicitly or implicitly include one or more features. Moreover, the term “a plurality of” refers to two or more than two, unless otherwise specified.

In the above embodiments, the description of each embodiment has its own emphasis, and for parts not described in detail in a certain embodiment, please refer to relevant description of other embodiments.

The embodiments, examples, and related technical features of the disclosure may be combined and replaced with each other without conflict.

The above are merely preferred embodiments of the disclosure, and do not limit the disclosure in any form. Any simple modifications, equivalent changes, and modifications made to the above embodiments according to the technical essence of the disclosure without departing from the contents of the technical solutions of the disclosure still fall within the scope of the technical solutions of the disclosure.

What is claimed is:

1. A display panel comprising:
a first electrode layer comprising a plurality of first electrodes;
an auxiliary layer disposed on a side of the first electrode layer, wherein the auxiliary layer comprises a plurality of auxiliary portions disposed corresponding to the plurality of first electrodes respectively, and each of the plurality of auxiliary portions is disposed on a side of one of the plurality of first electrodes;
a light-emitting layer disposed on a side of the auxiliary layer away from the first electrode layer, wherein the light-emitting layer comprises a plurality of light-emitting portions disposed corresponding to the plurality of auxiliary portions respectively, and each of the light-emitting portions is disposed on a side of one of the auxiliary portions away from corresponding one of the plurality of first electrodes; and
a second electrode layer disposed on a side of the light-emitting layer away from the auxiliary layer;
wherein the auxiliary portions comprise a first material, and the light-emitting portions comprise quantum dots and connecting structures connected between the quantum dots; and the connecting structures are formed by a second material substituted by a crosslinking structure, the second material is the same as the first material, and the quantum dots are connected by the connecting structures through the crosslinking structure.

2. The display panel of claim 1, wherein the first material is selected from at least one of the following compounds:

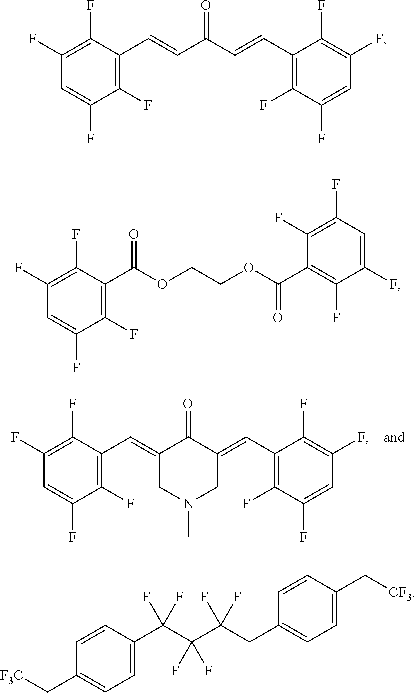

3. The display panel of claim 2, wherein the connecting structures comprise at least one of structures represented by the following formulae: 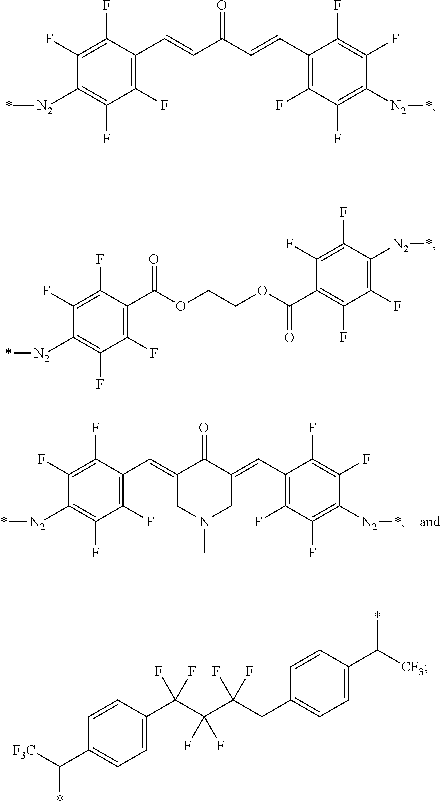
wherein * indicates a linking site.

4. The display panel of claim 1, wherein one or more hydrogen atoms in the second material are substituted by the crosslinking structure to form the connecting structures.

5. The display panel of claim 1, wherein the light-emitting portions comprise a first light-emitting portion, a second light-emitting portion, and a third light-emitting portion; the quantum dots in the first light-emitting portion, the quantum dots in the second light-emitting portion, and the quantum dots in the third light-emitting portion are independently selected from one of red quantum dots, green quantum dots, and blue quantum dots; and the quantum dots in the first light-emitting portion, the quantum dots in the second light-emitting portion, and the quantum dots in the third light-emitting portion are different from each other; and
wherein the auxiliary portions comprise a first auxiliary portion disposed between one of the first electrodes and the first light-emitting portion, a second auxiliary portion disposed between one of the first electrodes and the second light-emitting portion, and a third auxiliary portion disposed between one of the first electrodes and the third light-emitting portion; and the first material in the first auxiliary portion, the first material in the second auxiliary portion, and the first material in the third auxiliary portion are the same or different.

6. The display panel of claim 1, wherein each of the quantum dots comprises a quantum dot body and a connecting group connected to the quantum dot body, and the quantum dot body is connected to the crosslinking structure through the connecting group; and
wherein the connecting group is selected from a substituted or unsubstituted alkyl group having 1 to 4 carbon atoms.

7. The display panel of claim 1, wherein the first material comprises a substituted or unsubstituted alkyl group having 1 to 4 carbon atoms.

8. The display panel of claim 1, wherein the display panel further comprises a first functional layer disposed between the auxiliary portions and the first electrodes, and an adhesion force between the auxiliary portions and the first functional layer is less than an adhesion force between the auxiliary portions and the light-emitting portions.

9. A method for manufacturing a display panel comprising:
forming a first electrode layer comprising a plurality of first electrodes;
forming an auxiliary layer and a light-emitting layer on a side of the first electrode layer, wherein the light-emitting layer is disposed on a side of the auxiliary layer away from the first electrode layer, the auxiliary layer comprises a plurality of auxiliary portions disposed corresponding to the plurality of first electrodes respectively, and the light-emitting layer comprises a plurality of light-emitting portions disposed corresponding to the plurality of auxiliary portions respectively; each of the plurality of auxiliary portions is disposed on a side of one of the plurality of first electrodes, and each of the light-emitting portions is disposed on a side of one of the auxiliary portions away from corresponding one of the plurality of first electrodes; the auxiliary portions comprise a first material, and the light-emitting portions comprise quantum dots and connecting structures connected between the quantum dots; and the connecting structures are formed by a second material substituted by a crosslinking structure, the second material is the same as the first material, and the quantum dots are connected by the connecting structures through the crosslinking structure; and
forming a second electrode layer on a side of the light-emitting layer away from the auxiliary layer.

10. The method for manufacturing the display panel of claim 9, wherein the step of forming an auxiliary layer and a light-emitting layer on a side of the first electrode layer comprises:
forming an auxiliary material layer comprising the auxiliary portions and a plurality of auxiliary portions to be etched by using the first material selected from at least one of the following compounds: 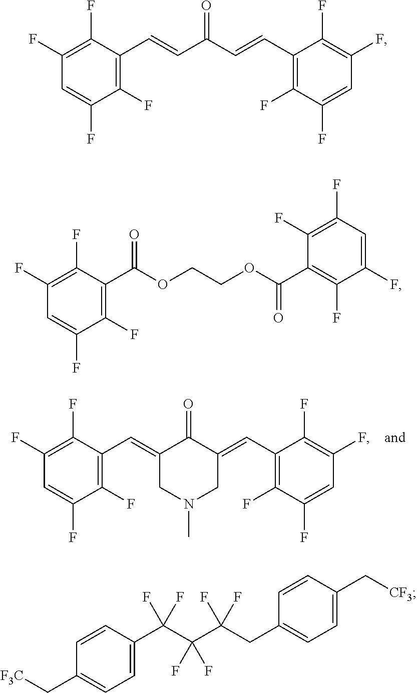
forming a first light-emitting material layer on a side of the auxiliary material layer away from the first electrode layer;
etching the first light-emitting material layer to form the light-emitting portions and a plurality of light-emitting portions to be etched, wherein each of the auxiliary portions is disposed between one of the light-emitting portions and corresponding one of the first electrodes, and each of the auxiliary portions to be etched is disposed between one of the light-emitting portions to be etched and corresponding one of the first electrodes; and
removing the light-emitting portions to be etched and the auxiliary portions to be etched to form the auxiliary layer and the light-emitting layer.

11. The method for manufacturing the display panel of claim 10, wherein the step of forming a first light-emitting material layer on a side of the auxiliary material layer away from the first electrode layer comprises:
providing quantum dots and a crosslinking material; and
forming the quantum dots and the connecting structures connected between the quantum dots by reaction of the quantum dots and the crosslinking material, wherein the crosslinking material comprises the first material substituted by a crosslinking group, and the crosslinking group is selected from at least one of an azide group, a bisacridinyl group, a carbon-carbon double bond, and a carbon-carbon triple bond.

12. The method for manufacturing the display panel of claim 11, wherein the crosslinking material is selected from at least one of the following compounds:

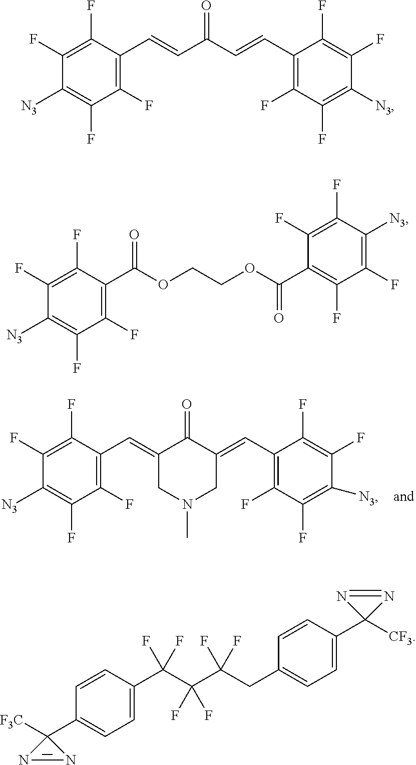

13. A display device comprising a display panel, wherein the display panel comprises:
a first electrode layer comprising a plurality of first electrodes;
an auxiliary layer disposed on a side of the first electrode layer, wherein the auxiliary layer comprises a plurality of auxiliary portions disposed corresponding to the plurality of first electrodes respectively, and each of the plurality of auxiliary portions is disposed on a side of one of the plurality of first electrodes;
a light-emitting layer disposed on a side of the auxiliary layer away from the first electrode layer, wherein the light-emitting layer comprises a plurality of light-emitting portions disposed corresponding to the plurality of auxiliary portions respectively, and each of the light-emitting portions is disposed on a side of one of the auxiliary portions away from corresponding one of the plurality of first electrodes; and
a second electrode layer disposed on a side of the light-emitting layer away from the auxiliary layer;
wherein the auxiliary portions comprise a first material, and the light-emitting portions comprise quantum dots and connecting structures connected between the quantum dots; and the connecting structures are formed by a second material substituted by a crosslinking structure, the second material is the same as the first material, and the quantum dots are connected by the connecting structures through the crosslinking structure.

14. The display device of claim 13, wherein the first material is selected from at least one of the following compounds:

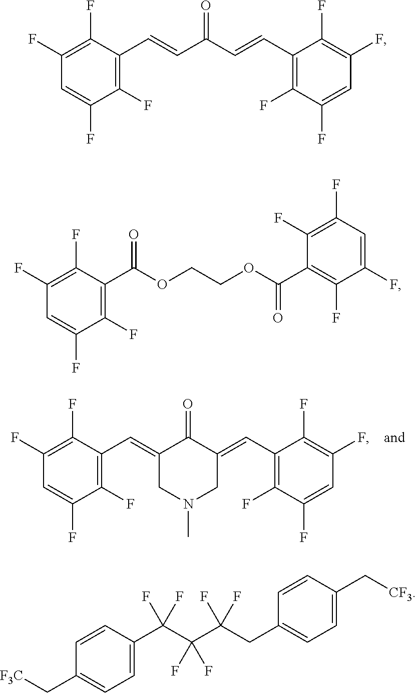

15. The display device of claim 14, wherein the connecting structures comprise at least one of structures represented by the following formulae: 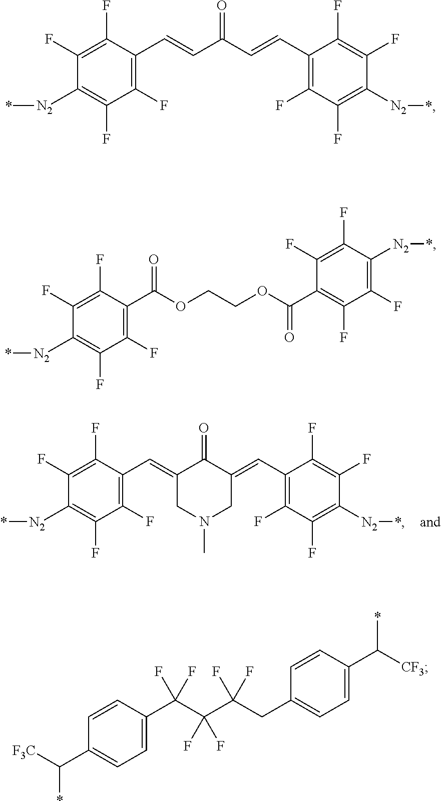
wherein * indicates a linking site.

16. The display device of claim 13, wherein one or more hydrogen atoms in the second material are substituted by the crosslinking structure to form the connecting structures.

17. The display device of claim 13, wherein the light-emitting portions comprise a first light-emitting portion, a second light-emitting portion, and a third light-emitting portion; the quantum dots in the first light-emitting portion, the quantum dots in the second light-emitting portion, and the quantum dots in the third light-emitting portion are independently selected from one of red quantum dots, green quantum dots, and blue quantum dots; and the quantum dots in the first light-emitting portion, the quantum dots in the second light-emitting portion, and the quantum dots in the third light-emitting portion are different from each other; and
wherein the auxiliary portions comprise a first auxiliary portion disposed between one of the first electrodes and the first light-emitting portion, a second auxiliary portion disposed between one of the first electrodes and the second light-emitting portion, and a third auxiliary portion disposed between one of the first electrodes and the third light-emitting portion; and the first material in the first auxiliary portion, the first material in the second auxiliary portion, and the first material in the third auxiliary portion are the same or different.

18. The display device of claim 13, wherein each of the quantum dots comprises a quantum dot body a quantum dot body and a connecting group connected to the quantum dot body, and the quantum dot body is connected to the crosslinking structure through the connecting group; and
wherein the connecting group is selected from a substituted or unsubstituted alkyl group having 1 to 4 carbon atoms.

19. The display device of claim 13, wherein the first material comprises a substituted or unsubstituted alkyl group having 1 to 4 carbon atoms.

20. The display device of claim 13, wherein the display panel further comprises a first functional layer disposed between the auxiliary portions and the first electrodes, and an adhesion force between the auxiliary portions and the first functional layer is less than an adhesion force between the auxiliary portions and the light-emitting portions.
